(19) United States
(12) Patent Application Publication
(10) Pub. No.: US 2017/0006206 A1
(43) Pub. Date: Jan. 5, 2017

(54) IMAGE SENSING DEVICE

(71) Applicant: SK hynix Inc., Gyeonggi-do (KR)

(72) Inventors: Jung-Eun SONG, Gyeonggi-do (KR); Jin-Seon KIM, Gyeonggi-do (KR); Min-Seok SHIN, Gyeonggi-do (KR); Si-Wook YOO, Gyeonggi-do (KR)

(21) Appl. No.: 14/950,144

(22) Filed: Nov. 24, 2015

(30) Foreign Application Priority Data
Jun. 30, 2015 (KR) 10-2015-0092585

(51) Int. Cl. H04N 5/235; H04N 5/376; H04N 5/378

(52) U.S. Cl. CPC H04N 5/2352; H04N 5/378; H04N 5/3765

(57) ABSTRACT

An image sensing device includes a readout circuit suitable for sequentially generating a plurality of image signals corresponding to each pixel signal, based on a ramp clock and a count clock; and a clock generation circuit suitable for generating the ramp clock and the count clock having different frequency relationships depending upon generation periods of the image signals, based on a gain code signal corresponding to an analog gain.

### CROSS-REFERENCE TO RELATED APPLICATION

This application claims priority under 35 U.S.C. §119 to Korean Patent Application No. 10-2015-0092585 flied on Jun. 30, 2015 in the Korean Intellectual Property Office, the disclosure of which is incorporated herein by reference in its entirety.

### TECHNICAL FIELD

Various embodiments of the present invention relate to a semiconductor design technology, and more particularly, to an image sensing device using a ramp signal.

### DISCUSSION OF THE RELATED ART

Image sensing devices capture an image by using the property of a semiconductor to react to light. Image sensing devices may be generally divided into image sensing devices using a charge coupled device (CCD) and image sensing devices using a complementary metal oxide semiconductor (CMOS). Image sensing devices employing a CMOS have an advantage in that analog and digital control circuits may be integrated in a single integrated circuit (IC).

Image sensing devices employing high dynamic range (HDR) technology have been suggested to provide a clear image. Generally, the HDR technology employs a multiple frame capture scheme, according to which images may be synthesized by capturing successive frames with different exposure times. However, this scheme may generally require substantial frame memory, and may therefore be difficult to use in the mobile field. Also, HDR technology is often subject to motion artifacts or blurring which may occur when synthesizing images comprising fast moving objects. In order to reduce motion artifacts, a technology capable of obtaining a result in which different exposure times are reflected by using different analog gains for the same pixel has been suggested.

Referring to FIG. 1 a timing diagram describing the operation of a conventional image sensing device is provided. For simplicity, only a first pixel signal VP<1> read out during a first unit row period 1ROW_P is shown in FIG. 1.

The first pixel signal VP<1> is outputted as a reset signal VRST<1> during a reset period of the first unit row period 1ROW_P, and is outputted as a data signal VSIG<1> during a data period of the first unit row period 1ROW_P.

Typically, during the reset period, the reset signal VRST<1> is converted into a digital signal DATA based on a low gain and also into a digital signal DATA based on a high gain. Hence, a ramp signal VR which ramps with a slope corresponding to the low gain and the reset signal VRST<1> are compared and a first count signal Low_Gain_RST_CNT corresponding to a comparison result is outputted as the digital signal DATA. Furthermore, the ramp signal VR which ramps with a slope corresponding to the high gain and the reset signal VRST<1> are compared and a second count signal High_Gain_RST_CNT corresponding to a comparison result is outputted as the digital signal DATA.

Furthermore, during the data period, the data signal VSIG<1> is converted into a digital signal DATA based on a high gain and is then converted into a digital signal DATA based on a low gain. That is, the ramp signal VR which ramps with the slope corresponding to the high gain and the data signal VSIG<I> are compared and a third count signal High_Gain_SIG_CNT corresponding to a comparison result is outputted as the digital signal DATA. Also, during the data period, the ramp signal VR which ramps with the slope corresponding to the low gain and the data signal VSIG<1> are compared and a fourth count signal Low_Gain_SIG_CNT corresponding to a comparison result is outputted as a digital signal DATA.

In this state, an image signal corresponding to a low light intensity is generated based on the second count signal High_Gain_RST_CNT and the third count signal High_Gain_SIG_CNT by using a DDS (digital double sampling) scheme, and an image signal corresponding to a high light intensity is generated based on the first count signal Low_Gain_RST_CNT and the fourth count signal Low_Gain_SIG_CNT by using the DDS scheme.

However, such a conventional image sensing device may be subject to a number of problems. For example, in order to convert the first pixel signal VP<1> into a digital signal DATA based on the low gain and also into a digital signal DATA based on the high gain, a conventional image sensing device typically employs a scheme for controlling the slope of the ramp signal VR.

Generally, heretofore, the scheme of controlling the slope of the ramp signal VR may include controlling the current magnitude bias current needed to generate the ramp signal VR. For example, a ramp signal VR which ramps with a slope corresponding to a low gain may be generated by providing a large bias current, while current magnitude a ramp signal VR which ramps with a slope corresponding to a high gain may be generated by providing a small magnitude bias current.

As a result, the ramp signal VR which ramps with a slope corresponding to a high gain may not ramp within a desired range as the bias current magnitude is controlled to be generally small. In this case, because the common mode level of the ramp signal VR becomes lower than the low gain, the ramp signal VR and the first pixel signal VP<1> are not auto-zeroed. Therefore, the digital signal DATA corresponding to the high gain may not have a desired value.

### SUMMARY

Various embodiments of the present invention are directed to an image sensing device in which a pixel signal and a ramp signal are precisely auto-zeroed for an analog gain.

In an embodiment of the present invention, an image sensing device may include: a readout circuit suitable for sequentially generating a plurality of image signals corresponding to each pixel signal, based on a ramp clock and a count clock; and a clock generation circuit suitable for generating the ramp clock and the count clock having different frequency relationships depending upon generation periods of the image signals, based on a gain code signal corresponding to an analog gain.

The plurality of image signals may include a first image signal and a second image signal having different light intensities.

The clock generation circuit may generate the ramp clock and the count clock having different frequencies, during the generation period of the first image signal, and generate the ramp clock and the count clock having the same first frequency, during the generation period of the second image signal.

The clock generation circuit may generate the count clock having the first frequency and the ramp clock having a second frequency, during the generation period of the first image signal.

The second frequency may be lower than the first frequency.

The clock generation circuit may generate the ramp clock having the first frequency and the count clock having a second frequency, during the generation period of the first image signal.

The second frequency may be higher than the first frequency.

The generation period of the first image signal may include a later period in a reset period during which a reset signal of the pixel signal is outputted from a pixel unit and an earlier period in a data period during which a data signal of the pixel signal is outputted from the pixel unit.

The generation period of the second image signal may include an earlier period in the reset period and a later period in the data period.

The readout circuit may generate the image signals during a unit row period.

In an embodiment of the present invention, an image sensing device may include: a counting unit suitable for generating a first image signal during a first generation period in a unit row period and generating a second image signal during a second generation period in the unit row period, based on a count clock and a comparison signal; a comparison unit suitable for generating the comparison signal based on a pixel signal and a ramp signal; a ramp signal generation block suitable for generating the ramp signal having a first slope during the first generation period and having a second slope during the second generation period, based on a ramp clock; a pixel unit suitable for generating the pixel signal during the unit row period; a ramp clock generation block suitable for generating the ramp clock having a first frequency during the second generation period and having a second frequency lower than the first frequency during the first generation period, based on a gain code signal corresponding to an analog gain; and a count clock generation block suitable for generating the count clock having the first frequency during the first generation period and the second generation period regardless of the gain code signal.

The first image signal may include an image signal corresponding to a low light intensity, and the second image signal may include an image signal corresponding to a high light intensity.

The first slope may be less steep than the second slope.

The pixel unit sequentially may output a reset signal and a data signal as the pixel signal during the unit row period, and the unit row period may include a reset period during which the reset signal is outputted and a data period during which the data signal is outputted.

The first generation period may include a later period of the reset period and an earlier period of the data period, and the second generation period may include an earlier period of the reset period and a later period of the data period.

In an embodiment of the present invention, an image sensing device may include: a counting unit suitable for generating a first image signal during a first generation period in a unit row period and generating a second image signal during a second generation period in the unit row period, based on a count clock and a comparison signal; a comparison unit suitable for generating the comparison signal based on a pixel signal and a ramp signal; a ramp signal generation block suitable for generating the ramp signal having the same slope during the first generation period and the second generation period, based on a ramp clock; a pixel unit suitable for generating the pixel signal during the unit row period; a count clock generation block suitable for generating the count clock having a first frequency during the second generation period and having a second frequency higher than the first frequency during the first generation period, based on a gain code signal corresponding to an analog gain; and a ramp clock generation block suitable for generating the ramp clock having the first frequency during the first generation period and the second generation period regardless of the gain code signal.

The first image signal may include an image signal corresponding to a low light intensity, and the second image signal may include an image signal corresponding to a high light intensity.

The first slope and the second slope may be the same.

The pixel unit sequentially may output a reset signal and a data signal as the pixel signal during the unit row period, and the unit row period may include a reset period during which the reset signal is outputted and a data period during which the data signal is outputted.

The generation period of the first image signal may include a later period of the reset period and an earlier period of the data period, and the generation period of the second image signal may include an earlier period of the reset period and a later period of the data period. According to embodiments of the invention, since a pixel signal and a ramp signal may be precisely auto-zeroed for an analog gain, a digital signal corresponding to the pixel signal may be more readily generated. Therefore, advantages are provided in that the operational reliability of the image sensing device is improved. These and other advantages will become apparent to a person skilled in this art after having read the present disclosure.

### BRIEF DESCRIPTION OF THE DRAWINGS

FIG. 1 is a timing diagram for describing an operation of a conventional image sensing device.

FIG. 2 is a block diagram illustrating an image sensing device in accordance with an embodiment of the present invention.

FIG. 3 is a more detailed diagram of a pixel unit and a first readout block, according to an embodiment of the invention.

FIG. 4 is a more detailed diagram of a ramp signal generation block, according to an embodiment of the invention.

FIG. 5 is a timing diagram for describing an operation of an image sensing device, according to an embodiment of the invention.

FIG. 6 is a block diagram illustrating an image sensing device, according to an embodiment of the invention.

FIG. 7 is a more detailed diagram of a pixel unit and a first readout block, according to an embodiment of the invention.

FIG. 8 is a more detailed diagram of a ramp signal generation block, according to an embodiment of the invention.

FIG. 9 is a timing diagram for describing an operation of an image sensing device, according to an embodiment of the invention.

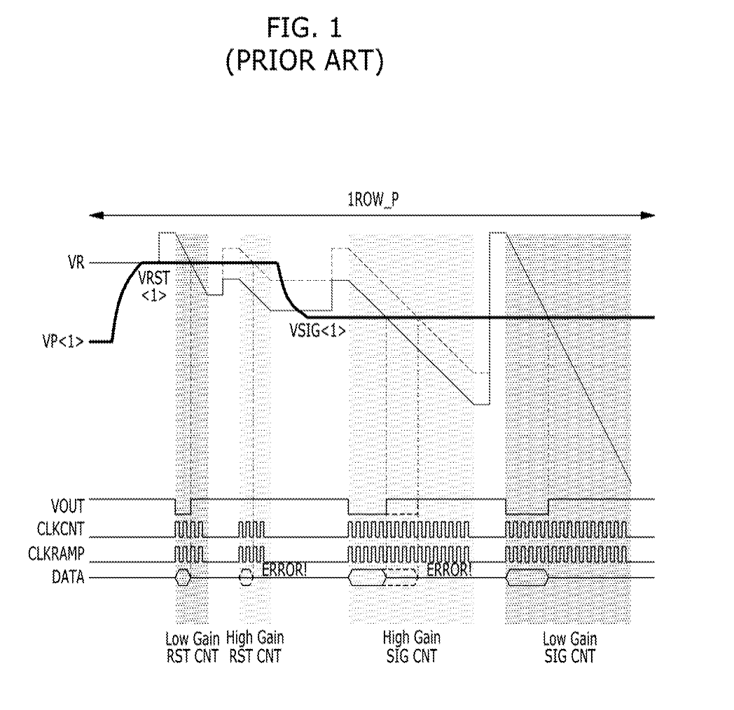

### DETAILED DESCRIPTION

Various embodiments will be described below in more detail with reference to the accompanying drawings. These embodiments are provided solely for the purpose of allowing those skilled in the art to better understand the invention and should not be construed as limiting the invention in any way. The present invention may be embodied in many other variations and should not be construed as being limited to the embodiments set forth herein. Also for simplicity, throughout the disclosure, like reference numerals refer to like parts throughout the various figures and embodiments of the present invention.

The drawings are not necessarily to scale and, in some instances, proportions may have been exaggerated to clearly illustrate features of the embodiments. It is also noted that in this specification, the terms “connected” or “coupled” refer to one component not only directly being connected or coupled to another component, but also to indirectly being connected or coupled to another component through an intermediate component. In addition, a singular form may include a plural form as long as it is not specifically mentioned.

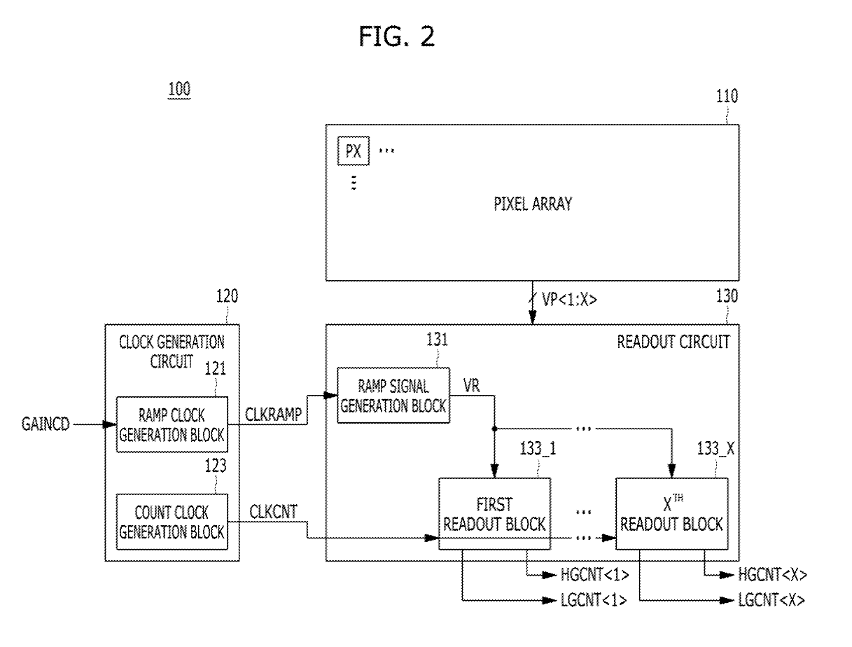

Referring now to FIG. 2 an image sensing device 100 in accordance with an embodiment of the present invention is provided in a block diagram.

The image sensing device 100 may include a pixel array 110, a clock generation circuit 120, and a readout circuit 130.

The pixel array 110 may include a plurality of pixel units PXs which are arranged in rows and columns. For example, the pixel array 110 may include X*Y number of pixel units PXs. The pixel array 110 may generate a plurality of pixel signals VP<1:X> for each row. For example, the pixel array 110 may generate first to X^{th} pixel signals VP<1:X> Y times. Namely, the pixel array 110 may simultaneously output first to X^{th} pixel signals VP<1:X> through first to X^{th} column lines from the X number of pixel units PXs arranged in a first row during a first unit row period, may simultaneously output first to X^{th} pixel signals VP<1:X> through the first to X^{th} column lines from the X number of pixel units PXs arranged in a second row during a second unit row period, . . . , and may simultaneously output first to X^{th} pixel signals VP<1:X> through the first to X^{th} column lines from the X number of pixel units PXs arranged in a Y^{th} row during a Y^{th} unit row period.

For reference, each of the first to X^{th} pixel signals VP<1:X> may include a reset signal and a data signal. For example, the pixel array 110 may output first to X^{th} reset signals VRST<1:X> as the first to X^{th} pixel signals VP<1:X> during a reset period of a unit row period, and then, may output first to X^{th} data signals VSIG<1:X> as the first to X^{th} pixel signals VP<1:X> during a data period of the unit row period.

The clock generation circuit 120 may generate a ramp clock CLKRAMP and a count clock CLKCNT having different frequency relationships depending upon the generation periods of an image signal (for example, HGCNT<1>) of a low light intensity and an image signal (for example, LGCNT<1>) of a high light intensity, in response to a gain code signal GAINCD corresponding to an analog gain. For example, the clock generation circuit 120 may generate the count clock CLKCNT having a first frequency and the ramp clock CLKRAMP having a second frequency lower than the first frequency during the generation period of an image signal corresponding to a low light intensity (hereinafter, referred to as a first generation period), and may generate the ramp clock CLKRAMP and the count clock CLKCNT having the same frequency during the generation period of an image signal corresponding to a high light intensity (hereinafter, referred to as a second generation period).

The first generation period may include a later period in the reset period and an earlier period in the data period. The second generation period may include an earlier period in the reset period and a later period in the data period.

The clock generation circuit 120 may include a ramp clock generation block 121 and a count clock generation block 123.

The ramp clock generation block 121 may generate the ramp clock CLKRAMP having the second frequency during the first generation period and has the first frequency during the second generation period, in response to the gain code signal GAINCD. For example, the ramp clock generation block 121 may output a first clock having the first frequency as the ramp clock CLKRAMP, during the second generation period, and may output a second clock which is generated by dividing the first clock, as the ramp clock CLKRAMP, during the first generation period. In other words, the ramp clock generation block 121 may generate the ramp clock CLKRAMP having a low frequency during the first generation period and has a high frequency during the second generation period.

The count clock generation block 123 may generate the count clock CLKCNT having the first frequency during the first generation period and the second generation period regardless of the gain code signal GAINCD.

The readout circuit 130 may include a ramp signal generation block 131, and first to X^{th} readout blocks 133_1 to 133_X.

The ramp signal generation block 131 may generate a ramp signal VR which ramps with a first slope corresponding to a high gain during the first generation period and ramps with a second slope corresponding to a low gain during the second generation period, in response to the ramp clock CLKRAMP. For example, the ramp signal generation block 131 may generate the ramp signal VR which ramps with the second slope within a reset threshold range corresponding to the reset signal, during the earlier period of the reset period, may generate the ramp signal VR which ramps with the first slope within the reset threshold range, during the later period of the reset period, may generate the ramp signal VR which ramps with the first slope within a data threshold range corresponding to the data signal, during the earlier period of the data period, and may generate the ramp signal VR which ramps with the second slope within the data threshold range, during the later period of the data period.

The first slope may be gentler than the second slope. Therefore, it is to be appreciated that the slope and the analog gain of the ramp signal VR are inversely proportional to each other.

The first to X^{th} readout blocks 133_1 to 133_X may generate first to X^{th} image signals HGCNT<1:X> of low light intensities and first to X^{th} image signals LGCNT<1:X> of high light intensities, corresponding to the first to X^{th} pixel signals VP<1:X>, in response to the ramp signal VR and the count clock CLKCNT. For example, the first to X^{th} readout blocks 133_1 to 133_X may generate the first to X^{th} image signals HGCNT<1:X> of the low light intensities by analog-to-digital converting the first to X^{th} pixel signals VP<1:X> with the high gain as the ramp signal VR which ramps with the first slope during the first generation period is used, and may generate the first to X^{th} image signals LGCNT<1:X> of the high light intensities by analog-to-digital converting the first to X^{th} pixel signals VP<1:X> with the low gain as the ramp signal VR which ramps with the second slope during the second generation period is used.

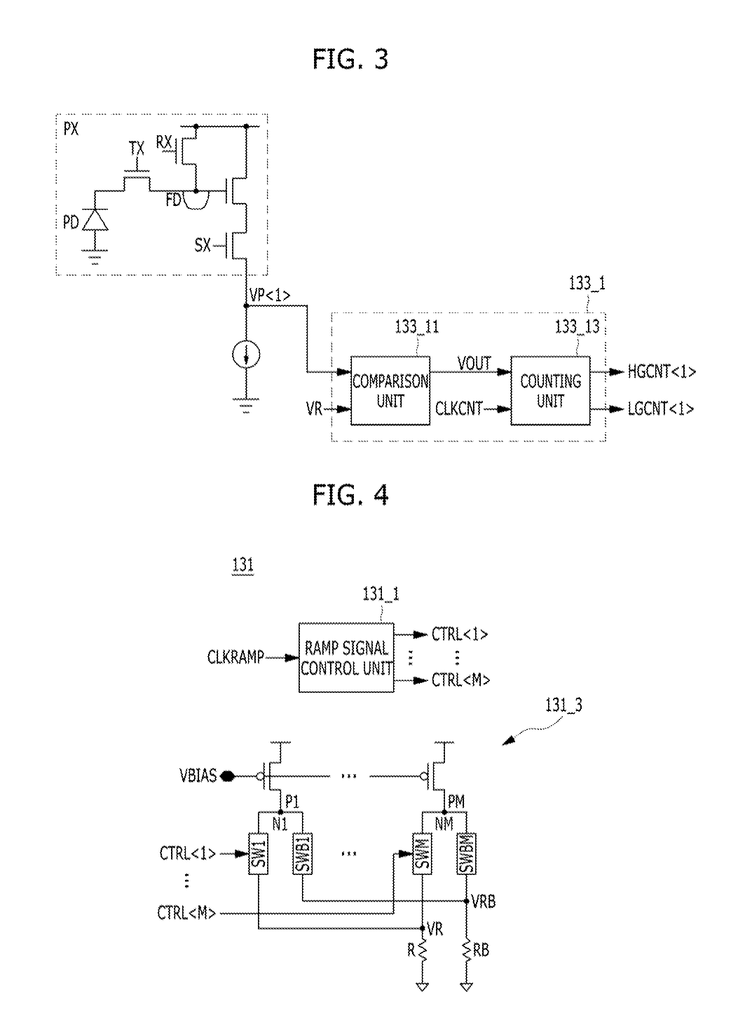

FIG. 3 is a detailed diagram of the pixel array 110 and the readout circuit 130 shown in FIG. 2.

In FIG. 3, for the sake of convenience in explanation, only one pixel unit PX electrically coupled to the first column line in the pixel array 110 and the first readout block 133_1 electrically coupled to the first column line in the readout circuit 130 are shown. Hereinafter, one pixel unit PX and the first readout block 133_1 electrically coupled to the first column line will be representatively described.

Referring to FIG. 3, the pixel unit PX may have a 4-transistor structure. Namely, the pixel unit PX may include a photodiode PD, a first transistor, a second transistor, a third transistor, and a fourth transistor. The photodiode PD may generate photocharges in response to incident light. The first transistor may reset a floating diffusion node FD with a predetermined voltage (for example, VDD) in response to a reset signal RX during the reset period. The second transistor may transmit the photocharges generated by the photodiode PD to the floating diffusion node FD in response to a transmission signal TX during the data period. The third transistor may transfer the first reset signal VRST<1> corresponding to the voltage of the floating diffusion node FD to the first column line as the first pixel signal VP<1> during the reset period, and may transfer the first data signal VSIG<1> corresponding to the voltage of the floating diffusion node FD to the first column line as the first pixel signal VP<1> during the data period. The fourth transistor may electrically couple the third transistor and the first column line in response to a select signal SX.

The first readout block 133_1 may include a comparison unit 133_11 and a counting unit 133_13.

The comparison unit 133_11 may compare the ramp signal VR and the first pixel signal VP<1> and generate a comparison signal VOUT. For example, during the earlier period of the reset period, the comparison unit 133_11 may compare the ramp signal VR which ramps with the second slope and the first reset signal VRST<1>, and may transition the comparison signal VOUT when the ramp signal VR and the first reset signal VRST<1> are auto-zeroed, as a result of the comparison. Further, during the later period of the reset period, the comparison unit 133_11 may compare the ramp signal VR which ramps with the first slope and the first reset signal VRST<1>, and may transition the comparison signal VOUT when the ramp signal VR and the first reset signal VRST<1> are auto-zeroed, as a result of the comparison. Moreover, during the earlier period of the data period, the comparison unit 133_11 may compare the ramp signal VR which ramps with the first slope and the first data signal VSIG<1>, and may transition the comparison signal VOUT when the ramp signal VR and the first data signal VSIG<1> are auto-zeroed, as a result of the comparison. Also, during the later period of the data period, the comparison unit 133_11 may compare the ramp signal VR which ramps with the second slope and the first data signal VSIG<1>, and may transition the comparison signal VOUT when the ramp signal VR and the first data signal VSIG<1> are auto-zeroed, as a result of the comparison.

The counting unit 133_13 may generate the first image signal HGCNT<1> of a low light intensity during the first generation period and may generate the first image signal LGCNT<1> of a high light intensity during the second generation period, in response to the comparison signal VOUT and the count clock CLKCNT. For example, the counting unit 133_13 may generate the first image signal HGCNT<1> of the low light intensity on the basis of a result of counting the comparison signal VOUT before transition, based on the count clock CLKCNT, during the later period of the reset period, and a result of counting the comparison signal VOUT before transition, based on the count clock CLKCNT, during the earlier period of the data period. At this time, the counting unit 133_13 may generate the first image signal HGCNT<1> of the low light intensity by using a DDS (digital double sampling) scheme. The DDS scheme is technology well-known in the art, and thus, detailed description thereof will be omitted herein. Further, the counting unit 133_13 may generate the image signal LGCNT<1> of the first high light intensity on the basis of a result of counting the comparison signal VOUT before transition, based on the count clock CLKCNT, during the earlier period of the reset period, and a result of counting the comparison signal VOUT before transition, based on the count clock CLKCNT, during the later period of the data period. At this time, the counting unit 133_13 may generate the image signal LGCNT<1> of the first high light intensity by using the DDS scheme.

Referring to FIG. 4 is a diagram illustration of an example of a suitable ramp signal generation block 131.

The ramp signal generation block 131 may include a ramp signal control unit 131_1 and a ramp signal generation unit 131_3.

The ramp signal control unit 131_1 may generate first to M^{th} control signals CTRL<1:M> in response to the ramp clock CLKRAMP. For example, the ramp signal control unit 131_1 may sequentially deactivate or activate the first to M^{th} control signals CTRL<1:M> whenever the ramp clock CLKRAMP toggles during the earlier period of the reset period. That is, during the earlier period of the reset period, the ramp signal control unit 131_1 may activate all the first to M^{th} control signals CTRL<1:M> when the ramp clock CLKRAMP toggles first, may deactivate the first control signal CTRL<1> among the first to M^{th} control signals CTRL<1:M> when the ramp clock CLKRAMP toggles second, may deactivate the first and second control signals CTRL<1:2> among the first to M^{th} control signals CTRL<1:M> when the ramp clock CLKRAMP toggles third, . . . , may deactivate the first to (M−1)^{th} control signals CTRL<1:M−1> among the first to M^{th} control signals CTRL<1:M> when the ramp clock CLKRAMP toggles M^{th}, and may deactivate all the first to M^{th} control signals CTRL<1:M> when the ramp clock CLKRAMP toggles (M+1)^{th}. In the same manner, the ramp signal control unit 131_1 may sequentially deactivate or activate the first to M^{th} control signals CTRL<1:M> whenever the ramp clock CLKRAMP toggles during the later period of the reset period, may sequentially deactivate or activate the first to M^{th} control signals CTRL<1:M> whenever the ramp clock CLKRAMP toggles during the earlier period of the data period, and may sequentially deactivate or activate the first to M^{th} control signals CTRL<1:M> whenever the ramp clock CLKRAMP toggles during the later period of the data period.

The ramp signal generation unit 131_3 may generate the ramp signal VR which ramps with the first slope during the first generation period and ramps with the second slope during the second generation period, in response to the first to M^{th} control signals CTRL<1:M> and a bias signal VBIAS. For example, the ramp signal generation unit 131_3 may generate the ramp signal VR which steeply ramps with the second slope during the earlier period of the reset period, may generate the ramp signal VR which gently ramps with the first slope during the later period of the reset period, may generate the ramp signal VR which gently ramps with the first slope during the earlier period of the data period, and may generate the ramp signal VR which steeply ramps with the second slope during the later period of the data period.

For example, the ramp signal generation unit 131_3 may include first to M^{th} driving sections P1 to PM, first to M^{th} switching sections SW1 to SWM, first to M^{th} inverting switching sections SWB1 to SWBM, a first resistor section R, and a second resistor section RB.

The first to M^{th} inverting switching sections SWB1 to SWBM and the second resistor section RB may be components for generating a ramp bar signal VRB which is in a differential relationship with respect to the ramp signal VR. Hereinafter, for the sake of convenience in explanation, descriptions for the first to M^{th} inverting switching sections SWB1 to SWBM and the second resistor section RB will be omitted, and descriptions will be made for only the first to M^{th} driving sections P1 to PM, the first to M^{th} switching sections SW to SWM and the first resistor section R.

The first to M^{th} driving sections P1 to PM may drive first to M^{th} nodes N1 to NM with a high voltage (for example, VDD) in response to the bias signal VBIAS. The bias signal VBIAS may have a fixed voltage level regardless of the analog gain, and all the first to M^{th} driving sections P1 to PM may have the same size. In this case, all currents respectively flowing through the first to M^{th} nodes N1 to NM may have the same magnitude or intensity. The currents respectively flowing through the first to M^{th} nodes N1 to NM may always have a constant current magnitude regardless of the analog gain.

The first to M^{th} switching sections SW1 to SWM may be electrically coupled between the first to M^{th} nodes N1 to NM and the output terminal of the ramp signal VR. The first to M^{th} switching sections SW1 to SWM may be sequentially switched in response to the first to M^{th} control signals CTRL<1:M>. For example, in response to the first to M^{th} control signals CTRL<1:M>, the first to M^{th} switching sections SW1 to SWM may be sequentially opened during the earlier period of the reset period, during the later period of the reset period, during the earlier period of the data period, and during the later period of the data period.

The first resistor section R may be electrically coupled between the output terminal of the ramp signal VR and the terminal of a low voltage (for example, VSS).

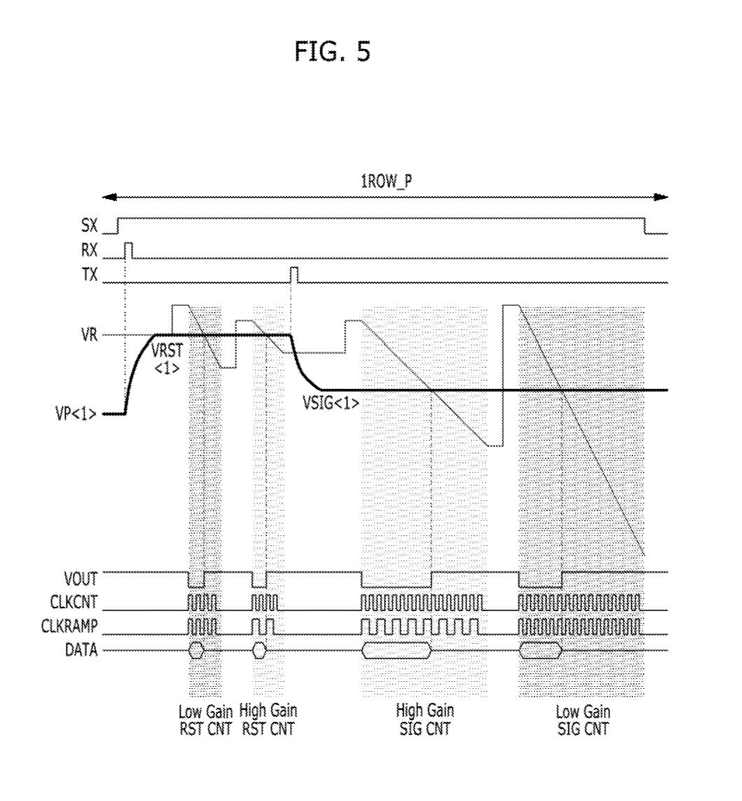

FIG. 5 is a timing diagram describing an operation of the image sensing device 100 of FIG. 2. It is to be noted that FIG. 5 shows only operations corresponding to the first pixel signal VP<1> generated by one pixel unit PX electrically coupled to the first column line.

Referring to FIG. 5, a unit row period 1ROW_P may include a period in which the select signal SX is activated, the reset period may be defined as a section from when the reset signal RX is activated to when the transmission signal TX is activated. The data period may be defined as a section from when the transmission signal TX is activated to when the select signal SX is deactivated.

(1) Operations of the Reset Period

The pixel unit PX may be electrically coupled to the first column line as the select signal SX is activated, and may generate the first reset signal VRST<1> as the first pixel signal VP<1> during the reset period as the reset signal RX is activated.

The clock generation circuit 120 may generate the ramp clock CLKRAMP and the count clock CLKCNT having the same frequency relationship, during the earlier period of the reset period, and may generate the ramp clock CLKRAMP and the count clock CLKCNT having different frequency relationship, during the later period of the reset period. For example, the ramp clock generation block 121 may generate the ramp clock CLKRAMP having the first frequency, in response to the gain code signal GAINCD corresponding to the low gain during the earlier period of the reset period, and may generate the ramp clock CLKRAMP having the second frequency, in response to the gain code signal GAINCD corresponding to the high gain during the later period of the reset period. The count clock generation block 123 may generate the count clock CLKCNT having the first frequency regardless of the gain code signal GAINCD, during the reset period.

The ramp signal generation block 131 may generate the ramp signal VR which steeply ramps with the second slope within the reset threshold range during the earlier period of the reset period and gently ramps with the first slope within the reset threshold range during the later period of the reset period, in response to the ramp clock CLKRAMP. For example, the ramp signal control unit 131_1 may sequentially deactivate the first to M^{th} control signals CTRL<1:M>, based on the ramp clock CLKRAMP during the earlier period of the reset period, and the ramp signal generation unit 131_3 may generate the ramp signal VR which drops by a voltage level corresponding to the unit current magnitude, in response to the first to M^{th} control signals CTRL<1:M> and the bias signal VBIAS during the earlier period of the reset period. As the ramp signal VR is generated based on the ramp clock CLKRAMP with the first frequency as a high frequency, the ramp signal VR may steeply ramp with the second slope. Similarly, the ramp signal control unit 131_1 may sequentially deactivate the first to M^{th} control signals CTRL<1:M>, based on the ramp clock CLKRAMP during the later period of the reset period, and the ramp signal generation unit 131_3 may generate the ramp signal VR which drops by the voltage level corresponding to the unit current magnitude, in response to the first to M^{th} control signals CTRL<1:M> and the bias signal VBIAS during the later period of the reset period. As the ramp signal VR is generated based on the ramp clock CLKRAMP with the second frequency as a low frequency, the ramp signal VR may gently ramp with the first slope.

In response to the ramp signal VR and the count clock CLKCNT, the first readout block 133_1 may analog-to-digital convert the first reset signal VRST<1> with the low gain during the earlier period in the reset period, and may analog-to-digital convert the first reset signal VRST<1> with the high gain during the later period in the reset period. For example, during the earlier period in the reset period, the comparison unit 133_11 may compare the ramp signal VR which ramps with the second slope and the first reset signal VRST<1>, and the counting unit 133_13 may output a first count signal Low_Gain_RST_CNT corresponding to a comparison result of the comparison unit 133_11, as a digital signal DATA. In succession, during the later period in the reset period, the comparison unit 133_11 may compare the ramp signal VR which ramps with the first slope and the first reset signal VRST<1>, and the counting unit 133_13 may output a second count signal High_Gain_RST_CNT corresponding to a comparison result of the comparison unit 133_11, as the digital signal DATA.

Now operations of the image sensing device 100 corresponding to the data period will be described.

The pixel unit PX may retain coupling with the first column line, as the select signal SX is continuously activated, and may generate the first data signal VSIG<1> as the first pixel signal VP<1> during the data period as the transmission signal TX is activated.

The clock generation circuit 120 may generate the ramp clock CLKRAMP and the count clock CLKCNT having different frequency relationship, during the earlier period of the data period, and may generate the ramp clock CLKRAMP and the count clock CLKCNT having the same frequency, during the later period of the data period. For example, the ramp clock generation block 121 may generate the ramp clock CLKRAMP having the second frequency, in response to the gain code signal GAINCD corresponding to the high gain during the earlier period of the data period, and may generate the ramp clock CLKRAMP having the first frequency, in response to the gain code signal GAINCD corresponding to the low gain during the later period of the data period. The count clock generation block 123 may generate the count clock CLKCNT having the first frequency regardless of the gain code signal GAINCD, during the data period.

The ramp signal generation block 131 may generate the ramp signal VR which gently ramps with the first slope within the data threshold range during the earlier period of the data period and steeply ramps with the second slope within the data threshold range during the later period of the data period, in response to the ramp clock CLKRAMP. For example, the ramp signal control unit 131_1 may sequentially deactivate the first to M^{th} control signals CTRL<1:M>, based on the ramp clock CLKRAMP during the earlier period of the data period, and the ramp signal generation unit 131_3 may generate the ramp signal VR which drops by the voltage level corresponding to the unit current magnitude, in response to the first to M^{th} control signals CTRL<1:M> and the bias signal VBIAS during the earlier period of the data period. As the ramp signal VR is generated based on the ramp clock CLKRAMP with the second frequency as a low frequency, the ramp signal VR may gently ramp with the first slope. Similarly, the ramp signal control unit 131_1 may sequentially deactivate the first to M^{th} control signals CTRL<1:M>, based on the ramp clock CLKRAMP during the later period of the data period, and the ramp signal generation unit 131_3 may generate the ramp signal VR which drops by the voltage level corresponding to the unit current magnitude, in response to the first to M^{th} control signals CTRL<1:M> and the bias signal VBIAS during the later period of the data period. As the ramp signal VR is generated based on the ramp clock CLKRAMP with the first frequency as a high frequency, the ramp signal VR may steeply ramp with the second slope.

In response to the ramp signal VR and the count clock CLKCNT, the first readout block 133_1 may analog-to-digital convert the first data signal VSIG<1> with the high gain during the earlier period of the data period, and may analog-to-digital convert the first data signal VSIG<1> with the low gain during the later period of the data period. For example, during the earlier period of the data period, the comparison unit 133_11 may compare the ramp signal VR which ramps with the first slope and the first data signal VSIG<1>, and the counting unit 133_13 may output a third count signal High_Gain_SIG_CNT corresponding to a comparison result of the comparison unit 133_11, as the digital signal DATA. In succession, during the later period of the data period, the comparison unit 133_11 may compare the ramp signal VR which ramps with the second slope and the first data signal VSIG<1>, and the counting unit 133_13 may output a fourth count signal Low_Gain_SIG_CNT corresponding to a comparison result of the comparison unit 133_11, as the digital signal DATA.

The counting unit 133_13 may generate the first image signal HGCNT<1> of the low light intensity based on the second count signal High_Gain_RST_CNT and the third count signal High_Gain_SIG_CNT by using the DDS scheme, and may generate the first image signal LGCNT<1> of the high light intensity based on the first count signal Low_Gain_RST_CNT and the fourth count signal Low_Gain_SIG_CNT by using the DDS scheme.

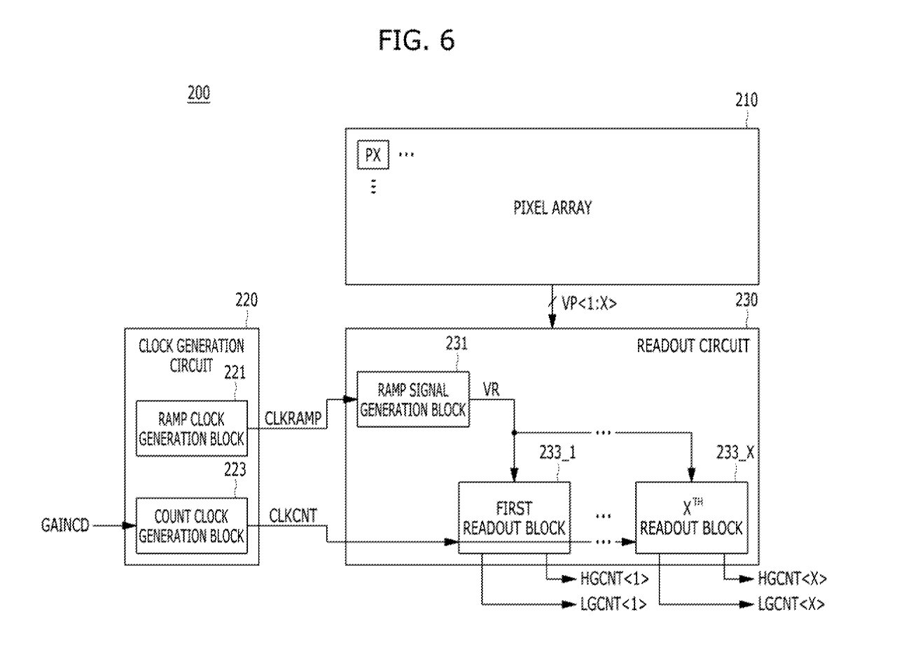

Referring now to FIG. 6 a block diagram illustrating an image sensing device 200 is provided, in accordance with an embodiment of the present invention.

The image sensing device 200 may include a pixel array 210, a clock generation circuit 220, and a readout circuit 230.

Since the pixel array 210 has have the similar configuration as the pixel array 110 shown in FIG. 2, detailed description thereof will be omitted herein.

In use, the clock generation circuit 220 may generate a ramp clock CLKRAMP and a count clock CLKCNT having different frequency relationships depending upon the generation periods of an image signal (for example, HGCNT<1>) of a low light intensity and an image signal (for example, LGCNT<1>) of a high light intensity, in response to a gain code signal GAINCD corresponding to an analog gain. For example, the clock generation circuit 220 may generate the ramp clock CLKRAMP having a first frequency and the count clock CLKCNT having a second frequency higher than the first frequency during the generation period of an image signal corresponding to a low light intensity (i.e., a first generation period), and may generate the ramp clock CLKRAMP and the count clock CLKCNT having the same frequency during the generation period of an image signal corresponding to a high light intensity (i.e., a second generation period).

The first generation period may include a later period of the reset period and an earlier period of the data period. The second generation period may include an earlier period of the reset period and a later period of the data period.

The clock generation circuit 220 may include a ramp clock generation block 221 and a count clock generation block 223.

The ramp clock generation block 221 may generate the ramp clock CLKRAMP having the first frequency during the first generation period and the second generation period regardless of the gain code signal GAINCD.

The count clock generation block 223 may generate the count clock CLKCNT having the second frequency during the first generation period and has the first frequency during the second generation period, in response to the gain code signal GAINCD. For example, the count clock generation block 223 may output a first clock having the first frequency, as the count clock CLKCNT, during the second generation period, and may output a second clock which is generated by multiplying the first clock, as the count clock CLKCNT, during the first generation period. In other words, the count clock generation block 223 may generate the count clock CLKCNT having a high frequency during the first generation period and has a low frequency during the second generation period.

The readout circuit 230 may include a ramp signal generation block 231, and first to X^{th} readout blocks 233_1 to 233_X.

The ramp signal generation block 231 may generate a ramp signal VR which ramps with the same slope regardless of the analog gain during the first and second generation periods, in response to the ramp clock CLKRAMP. For example, the ramp signal generation block 231 may generate the ramp signal VR which ramps two times with the same slope within a reset threshold range during the reset period, and may generate the ramp signal VR which ramps two times with the same slope within a data threshold range during the data period.

Since the first to X^{th} readout blocks 233_1 to 233_X have the similar configurations to the first to X^{th} readout blocks 133_1 to 133_X shown in FIG. 2, detailed descriptions thereof will be omitted herein.

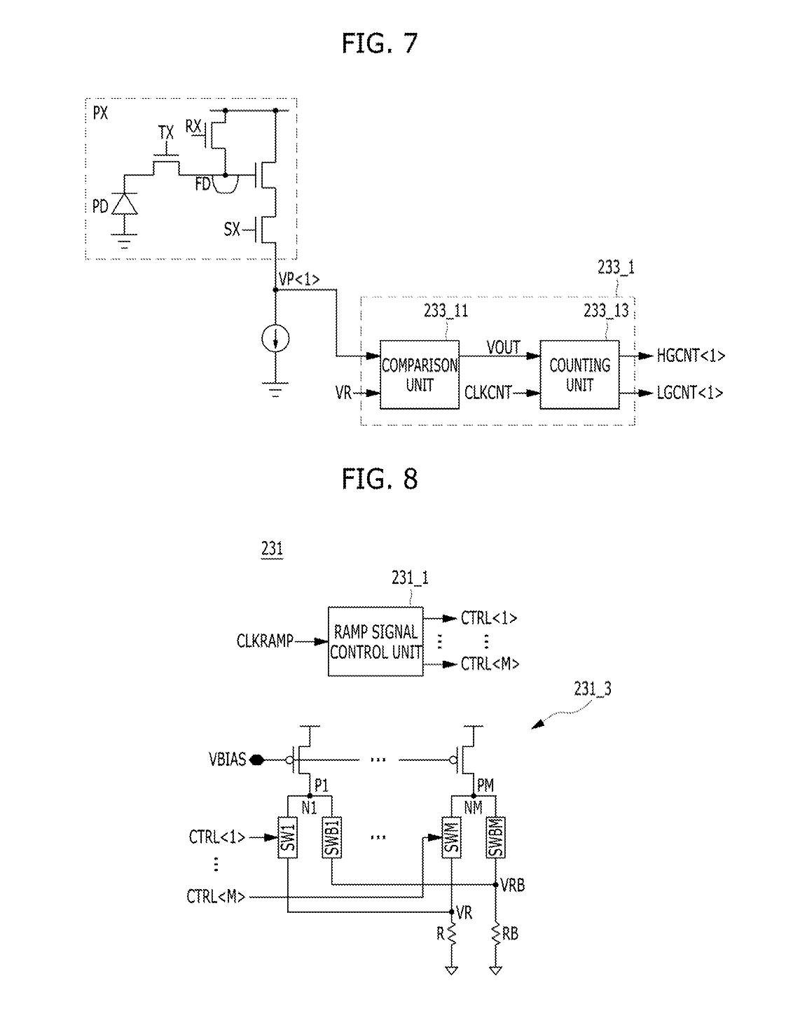

FIG. 7 is a diagram of the pixel unit PX and the first readout block 233_1 shown in FIG. 6. Since the pixel unit PX and the first readout block 233_1 may have the similar configurations to the pixel unit PX and the first readout block 133_1 shown in FIG. 3, detailed descriptions thereof will be omitted herein.

A counting unit 233_13 may generate a first image signal HGCNT<1> of a low light intensity corresponding to a first pixel signal VP<1>, based on the count clock CLKCNT having the second frequency corresponding to the high gain, during the first generation period, and may generate a first image signal LGCNT<1> of a high light intensity corresponding to the first pixel signal VP<1>, based on the count clock CLKCNT having the first frequency corresponding to the low gain, during the second generation period.

Referring to FIG. 8 an example of a ramp signal generation block 231 is provided.

The ramp signal generation block 231 may include a ramp signal control unit 231_1 and a ramp signal generation unit 231_3.

Since the ramp signal generation block 231 has many features similar to the ramp signal generation block 131 shown in FIG. 4, detailed description thereof is omitted.

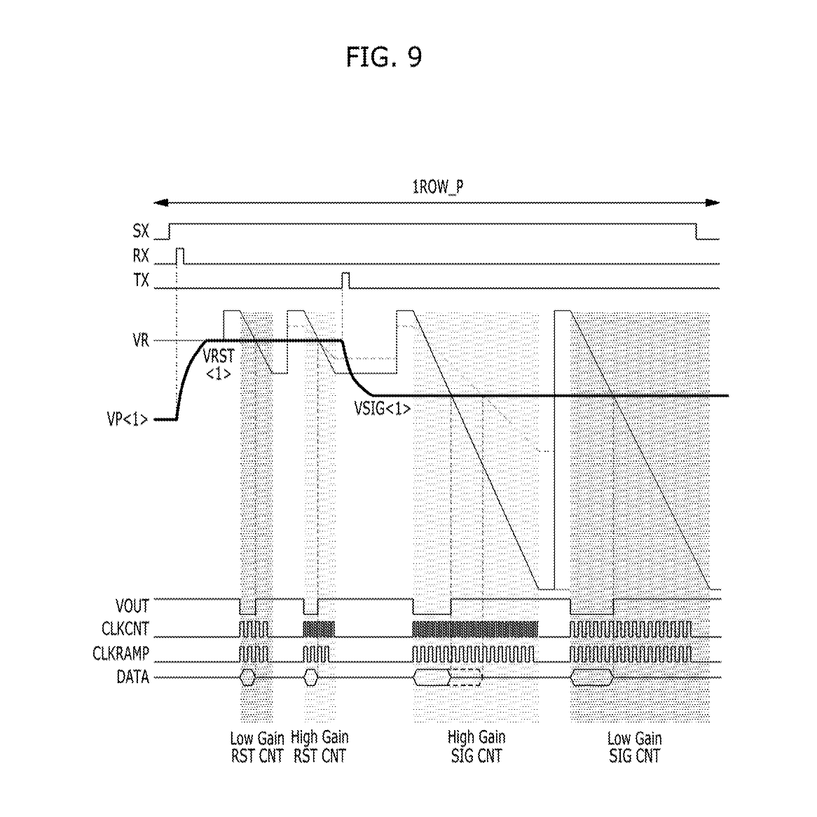

FIG. 9 is a timing diagram describing an operation of the image sensing device 200 shown in FIG. 6. It is to be noted that FIG. 9 shows only operations corresponding to the first pixel signal VP<1> generated by one pixel unit PX electrically coupled to a first column line.

A unit row period 1ROW_P may include a period in which a select signal SX is activated, the reset period may be defined as a section from when a reset signal RX is activated to when a transmission signal TX is activated. The data period may be defined as a section from when the transmission signal TX is activated to when the select signal SX is deactivated.

In operation, the pixel unit PX may be electrically coupled to the first column line as the select signal SX is activated. The pixel unit PX may also generate a first reset signal VRST<1> as the first pixel signal VP<1> during the reset period as the reset signal RX is activated.

The clock generation circuit 220 may generate the ramp clock CLKRAMP and the count clock CLKCNT having the same frequency during the earlier period in the reset period, and may generate the ramp clock CLKRAMP and the count clock CLKCNT having a different frequency relationship during the later period in the reset period. For example, the ramp clock generation block 221 may generate the ramp clock CLKRAMP having a first frequency regardless of the gain code signal GAINCD, during the reset period. Conversely, the count clock generation block 223 may generate the count clock CLKCNT having a first frequency, in response to the gain code signal GAINCD corresponding to the low gain during the earlier period of the reset period, and may generate the count clock CLKCNT having a second frequency, in response to the gain code signal GAINCD corresponding to the high gain during the later period of the reset period.

The ramp signal generation block 231 may generate a ramp signal VR which ramps two times with the same slope within the reset threshold range during the reset period, in response to the ramp clock CLKRAMP. For example, a ramp signal control unit 231_1 may sequentially deactivate first to M^{th} control signals CTRL<1:M>, based on the ramp clock CLKRAMP during the earlier period in the reset period, and a ramp signal generation unit 231_3 may generate the ramp signal VR which drops by a voltage level corresponding to a unit current magnitude, in response to the first to M^{th} control signals CTRL<1:M> and a bias signal VBIAS during the earlier period in the reset period. Similarly, the ramp signal control unit 231_1 may sequentially deactivate the first to M^{th} control signals CTRL<1:M>, based on the ramp clock CLKRAMP during the later period in the reset period, and the ramp signal generation unit 231_3 may generate the ramp signal VR which drops by the voltage level corresponding to the unit current magnitude, in response to the first to M^{th} control signals CTRL<1:M> and the bias signal VBIAS during the later period in the reset period.

In response to the ramp signal VR and the count clock CLKCNT, the first readout block 233_1 may analog-to-digital convert the first reset signal VRST<1> with the low gain during the earlier period in the reset period, and may analog-to-digital convert the first reset signal VRST<1> with the high gain during the later period in the reset period. For example, during the earlier period in the reset period, a comparison unit 233_11 may compare the ramp signal VR and the first reset signal VRST<1>, and may generate a comparison signal VOUT which transitions when the ramp signal VR and the first reset signal VRST<1> are auto-zeroed, as a result of the comparison. During the earlier period in the reset period, a counting unit 233_13 may count the comparison signal VOUT based on the count clock CLKCNT having the first frequency, and may output a first count signal Low_Gain_RST_CNT analog-to-digital converted with the low gain, as a digital signal DATA. In succession, during the later period in the reset period, the comparison unit 233_11 may compare the ramp signal VR and the first reset signal VRST<1>, and may generate the comparison signal VOUT which transitions when the ramp signal VR and the first reset signal VRST<1> are auto-zeroed, as a result of the comparison. During the later period in the reset period, the counting unit 233_13 may count the comparison signal VOUT based on the count clock CLKCNT having the second frequency, and may output a second count signal High_Gain_RST_CNT analog-to-digital converted with the high gain, as the digital signal DATA.

In operation, the pixel unit PX may retain coupling with the first column line, as the select signal SX is continuously activated, and may generate a first data signal VSIG<1> as the first pixel signal VP<1> during the data period as the transmission signal TX is activated.

The clock generation circuit 220 may generate the ramp clock CLKRAMP and the count clock CLKCNT having different frequency relationship, during the earlier period in the data period, and may generate the ramp clock CLKRAMP and the count clock CLKCNT having the same frequency, during the later period in the data period. For example, the ramp clock generation block 221 may generate the ramp clock CLKRAMP having the first frequency regardless of the gain code signal GAINCD, during the data period. Conversely, the count clock generation block 223 may generate the count clock CLKCNT having the second frequency, in response to the gain code signal GAINCD corresponding to the high gain during the earlier period of the data period, and may generate the count clock CLKCNT having the first frequency, in response to the gain code signal GAINCD corresponding to the low gain during the later period of the data period.

The ramp signal generation block 231 may generate the ramp signal VR which ramps two times with the same slope within the data threshold range during the data period, in response to the ramp clock CLKRAMP. For example, the ramp signal control unit 231_1 may sequentially deactivate the first to M^{th} control signals CTRL<1:M>, based on the ramp clock CLKRAMP during the earlier period in the data period, and the ramp signal generation unit 231_3 may generate the ramp signal VR which drops by the voltage level corresponding to the unit current magnitude, in response to the first to M^{th} control signals CTRL<1:M> and the bias signal VBIAS during the earlier period in the data period. Similarly, the ramp signal control unit 231_1 may sequentially deactivate the first to M^{th} control signals CTRL<1:M>, based on the ramp clock CLKRAMP during the later period of the data period, and the ramp signal generation unit 231_3 may generate the ramp signal VR which drops by the voltage level corresponding to the unit current magnitude, in response to the first to M^{th} control signals CTRL<1:M> and the bias signal VBIAS during the later period in the data period.

In response to the ramp signal VR and the count clock CLKCNT, the first readout block 233_1 may analog-to-digital convert the first data signal VSIG<1> with the high gain during the earlier period in the data period, and may analog-to-digital convert the first data signal VSIG<1> with the low gain during the later period in the data period. For example, during the earlier period in the data period, the comparison unit 233_11 may compare the ramp signal VR and the first data signal VSIG<1>, and may generate the comparison signal VOUT which transitions when the ramp signal VR and the first data signal VSIG<1> are auto-zeroed, as a result of the comparison. During the earlier period in the data period, the counting unit 233_13 may count the comparison signal VOUT based on the count clock CLKCNT having the second frequency, and may output a third count signal High_Gain_SIG_CNT analog-to-digital converted with the high gain, as the digital signal DATA. In succession, during the later period in the data period, the comparison unit 233_11 may compare the ramp signal VR and the first data signal VSIG<1>, and may generate the comparison signal VOUT which transitions when the ramp signal VR and the first data signal VSIG<1> are auto-zeroed, as a result of the comparison. During the later period in the data period, the counting unit 233_13 may count the comparison signal VOUT based on the count clock CLKCNT having the first frequency, and may output a fourth count signal Low_Gain_SIG_CNT analog-to-digital converted with the low gain, as the digital signal DATA.

The counting unit 233_13 may generate the first image signal HGCNT<1> of the low light intensity based on the second count signal High_Gain_RST_CNT and the third count signal High_Gain_SIG_CNT by using a digital double sampling (DDS) scheme, and may generate the first image signal LGCNT<1> of the high light intensity based on the first count signal Low_Gain_RST_CNT and the fourth count signal Low_Gain_SIG_CNT by using the DDS scheme.

As is apparent from the above descriptions, according to the embodiments, advantages are provided in that, since an analog gain is controlled regardless of the magnitude of a ramp signal current, the ramp signal may be ramped within a predetermined threshold range.

Although various embodiments have been described for illustrative purposes, it will be apparent to those skilled in the art that various changes and modifications may be made without departing from the spirit and scope of the invention as defined in the following claims.

What is claimed is:

1. An image sensing device comprising:
a readout circuit suitable for sequentially generating a plurality of image signals corresponding to each pixel signal, based on a ramp clock and a count clock; and
a clock generation circuit suitable for generating the ramp clock and the count clock having different frequency relationships depending upon generation periods of the image signals, based on a gain code signal corresponding to an analog gain.

2. The image sensing device according to claim 1, wherein the image signals comprise a first image signal and a second image signal having different light intensities.

3. The image sensing device according to claim 2, wherein the clock generation circuit generates the ramp clock and the count clock having different frequencies during the generation period of the first image signal, and generates the ramp clock and the count clock having the same frequency during the generation period of the second image signal.

4. The image sensing device according to claim 3, wherein the clock generation circuit generates the count clock having a first frequency and the ramp clock having a second frequency during the generation period of the first image signal.

5. The image sensing device according to claim 4, wherein the second frequency is lower than the first frequency.

6. The image sensing device according to claim 3, wherein the clock generation circuit generates the ramp clock having a first frequency and the count clock having a second frequency, during the generation period of the first image signal.

7. The image sensing device according to claim 6, wherein the second frequency is higher than the first frequency.

8. The image sensing device according to claim 3, wherein the generation period of the first image signal comprises a later period in a reset period during which a reset signal of the pixel signal is outputted from a pixel unit and an earlier period in a data period during which a data signal of the pixel signal is outputted from the pixel unit.

9. The image sensing device according to claim 8, wherein the generation period of the second image signal comprises an earlier period in the reset period and a later period in the data period.

10. The image sensing device according to claim 1, wherein the readout circuit generates the image signals during a unit row period.

11. An image sensing device comprising:
a counting unit suitable for generating a first image signal during a first generation period in a unit row period and generating a second image signal during a second generation period in the unit row period, based on a count clock and a comparison signal;
a comparison unit suitable for generating the comparison signal based on a pixel signal and a ramp signal;
a ramp signal generation block suitable for generating the ramp signal having a first slope during the first generation period and having a second slope during the second generation period, based on a ramp clock;
a pixel unit suitable for generating the pixel signal during the unit row period;
a ramp clock generation block suitable for generating the ramp clock having a first frequency during the second generation period and having a second frequency during the first generation period, based on a gain code signal corresponding to an analog gain; and
a count clock generation block suitable for generating the count clock having the first frequency during the first generation period and the second generation period regardless of the gain code signal.

12. The image sensing device according to claim 11, wherein the second frequency is lower than the first frequency.

13. The image sensing device according to claim 11,
wherein the first image signal comprises an image signal corresponding to a low light intensity, and
wherein the second image signal comprises an image signal corresponding to a high light intensity.

14. The image sensing device according to claim 13, wherein the first slope is less steep than the second slope.

15. The image sensing device according to claim 11,
wherein the pixel unit sequentially outputs a reset signal and a data signal as the pixel signal during the unit row period, and
wherein the unit row period comprises a reset period during which the reset signal is outputted and a data period during which the data signal is outputted.

16. The image sensing device according to claim 15,
wherein the first generation period comprises a later period of the reset period and an earlier period of the data period, and
wherein the second generation period comprises an earlier period of the reset period and a later period of the data period.

17. An image sensing device comprising:
a counting unit suitable for generating a first image signal during a first generation period in a unit row period and generating a second image signal during a second generation period in the unit row period, based on a count clock and a comparison signal;
a comparison unit suitable for generating the comparison signal based on a pixel signal and a ramp signal;
a ramp signal generation block suitable for generating the ramp signal having the same slope during the first generation period and the second generation period, based on a ramp clock;
a pixel unit suitable for generating the pixel signal during the unit row period;
a count clock generation block suitable for generating the count clock having a first frequency during the second generation period and having a second frequency during the first generation period, based on a gain code signal corresponding to an analog gain; and
a ramp clock generation block suitable for generating the ramp clock having the first frequency during the first generation period and the second generation period regardless of the gain code signal.

18. The image sensing device according to claim 17, wherein the second frequency is higher than the first frequency.

19. The image sensing device according to claim 17,
wherein the first image signal comprises an image signal corresponding to a low light intensity, and
wherein the second image signal comprises an image signal corresponding to a high light intensity.

20. The image sensing device according to claim 17,
wherein the pixel unit sequentially outputs a reset signal and a data signal as the pixel signal during the unit row period, and
wherein the unit row period comprises a reset period during which the reset signal is outputted and a data period during which the data signal is outputted.

21. The image sensing device according to claim 20,
wherein the generation period of the first image signal comprises a later period of the reset period and an earlier period of the data period, and
wherein the generation period of the second image signal comprises an earlier period of the reset period and a later period of the data period.
